(19) United States
(12) Patent Application Publication
(10) Pub. No.: US 2007/0019695 A1
(43) Pub. Date: Jan. 25, 2007

(54) Optical and element

(75) Inventors: Shinji Iio, Tokyo (JP); Masayuki Suehiro, Tokyo (JP); Chie Sato, Tokyo (JP); Morio Wada, Tokyo (JP); Katsuya Ikezawa, Tokyo (JP); Daisuke Hayashi, Tokyo (JP); Akira Miura, Tokyo (JP); Tsuyoshi Yakihara, Tokyo (JP); Shinji Kobayashi, Tokyo (JP); Sadaharu Oka, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/487,468

(22) Filed: Jul. 17, 2006

(30) Foreign Application Priority Data
Jul. 19, 2005 (JP) P. 2005-208824

(51) Int. Cl. H01S 5/00

(52) U.S. Cl. 372/45.013; 372/45.01

(57) ABSTRACT

An optical AND element includes a semiconductor laser having a plurality of saturable absorption regions on an optical waveguide, electrodes of the saturable absorption regions being separated from each other, and a light inputting section for inputting light into the respective saturable absorption regions.

This application claims foreign priority based on Japanese Patent Application No. 2005-208824, filed Jul. 19, 2005, the content of which is incorporated herein by reference in its entirety.

### BACKGROUND OF THE INVENTION

1. Field of the Invention

The present invention relates to a structure of an optical AND element necessary for an optical label process in a next generation optical communication network such as an optical burst network or an optical packet network.

2. Description of the Related Art

Most of WANs (Wide Area Network) or LANs (Local Area Network) that are currently put to practical use are networks using electric signals as transmission media. A communication using light as transmission media is employed only in a trunk part for transmitting a large quantity of data and a part of other parts.

Further, the communication is a point-to-point communication and has not been yet developed to a communication network that may be said to be a “photonic network”. In practice, a large quantity of data does not need to be transmitted to an end terminal of the network in view of the present needs of the network.

However, it is expected in the future that even a PD (photodiode) of a end terminal transmits and receives a large quantity of data and simultaneity of the data will be required. As a technique for solving this problem, an optical burst network or an optical packet network is proposed that is currently studied and developed but has not been put to practical use.

This technique uses a network in which a data signal is converted to optical burst data or optical packet data, and switched in an optical form without converting the data to an electric signal until the data reaches the end terminal. In the optical burst network, a data transfer delay time can be substantially shortened compared to that of a current network that frequently uses an electric-optic conversion. In the optical packet network, the real time characteristics of the data can be further maintained.

In these networks, a data unit to be transmitted is an optical burst unit or an optical packet unit. In a header part, or a signaling packet in the case of the optical burst, an optical label part is provided in which a transmitting source or a destination address of the optical burst or optical packet is described.

FIG. 3 is a block diagram showing a related example for performing an electrical logic process. In this example, all optical data is received by PDs 20, and optical signals are converted to electric signals to execute an AND operation by an electric AND circuit. That is, the optical signals (not illustrated) are converted to electric signals by the PDs 20, and amplified by AMPs 21 to carry out a logic process in an AND latch circuit 30.

FIG. 4 is a block diagram showing another related example that executes the AND operation of the outputs of PDs, which are electric signals converted from optical signals, by using the PDs 20 and an RTD (Resonant Tunneling Diode) 40.

A related example of an optical exclusive OR array circuit using an optical element is disclosed in JP-A-4-241334.

In determination of the optical label that is necessary in the optical burst network or the optical packet network, an optical AND circuit is provided after a serial-parallel conversion of light. The optical AND circuit includes an optical AND circuit of the electrical logic process that executes the AND operation by using the electric AND circuit after all the optical data has been received by the PDs and the optical signals have been converted into electric signals, as in the related example shown in FIG. 3. The optical AND circuit may also include an optical logical processing circuit as shown in FIG. 4, that executes the AND operation of the outputs of the PDs, which are electric signals converted from optical signals, by using the PDs and the RTD.

However, in the case of the electrical logic process, a number of necessary elements is large and many electric connections are required, so that a cost is very high. Further, a high-speed process such as 40 Gbps is relatively difficult. In a process in the related optical logical processing circuit, there is no problem in terms of high speed. However, the number of elements is also large, and accordingly, a problem arises that a cost is high.

### SUMMARY OF THE INVENTION

The present invention has been made in view of the above circumstances, and provides an optical AND element whose structure is relatively simple.

In some implementations, an optical AND element of the invention comprising:

a semiconductor laser having a plurality of saturable absorption regions on an optical waveguide, electrodes of the saturable absorption regions being separated from each other; and

a light inputting section for inputting light into the respective saturable absorption regions.

The optical AND element of the invention further comprising:
a current supplying section that independently supplies an electric current to the respective saturable absorption regions.

In the optical AND element of the invention, the light is inputted into the respective saturable absorption regions by directly connecting an optical fiber to the optical AND element.

In the optical AND element of the invention, the light is inputted into the respective saturable absorption regions through the optical waveguide.

According to the invention, an ordinary current injecting area of a semiconductor laser is divided into a plurality of parts in which electrodes are separated, and thus manufacture is easy, and a cost and size can be reduced.

### BRIEF DESCRIPTION OF THE DRAWINGS

Fig.1 is an enlarged plan view of the main parts of an optical AND element according to an embodiment of the present invention.

FIG. 2 is an enlarged plan view of the main parts of another optical AND element according to an embodiment of the present invention.

FIG. 3 is a block diagram showing a related optical AND element.

FIG. 4 is a block diagram showing another example of a related optical AND element.

### DESCRIPTION OF THE PREFERRED EMBODIMENTS

Now, referring to the drawings, the present invention will be described below in detail.

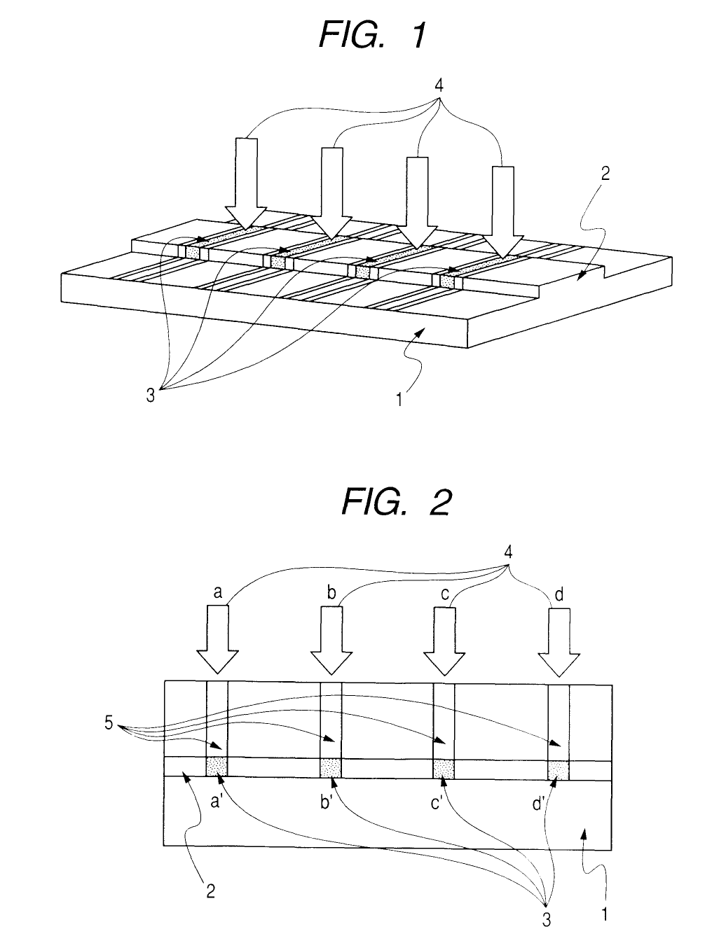

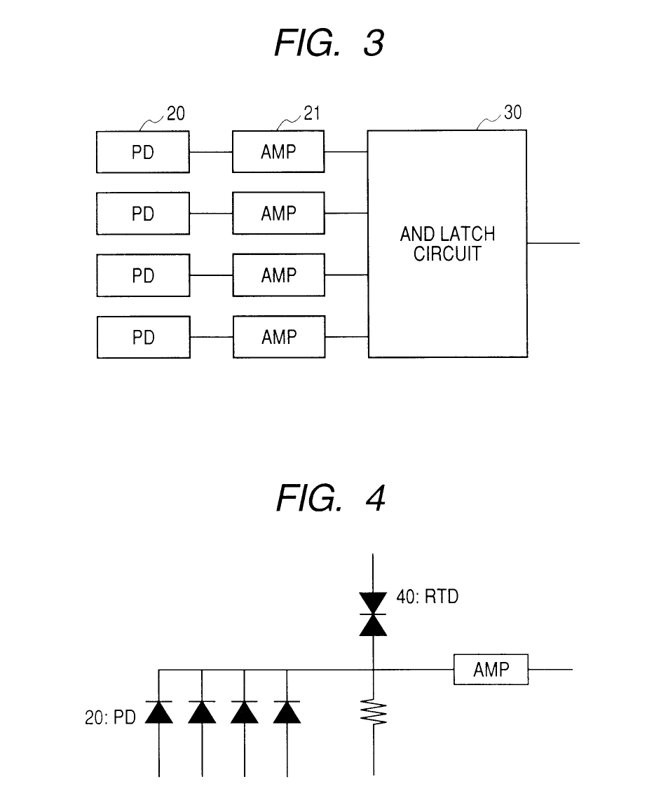

FIG. 1 is an enlarged plan view of one embodiment of an optical AND element of the present invention that shows the main parts.

In the drawing, reference numeral 1 designates a semiconductor laser having saturable absorption regions, wherein the saturable absorption regions 3 of which electrodes are separated from each other (in the drawing, four positions at intervals of equal distances) in the longitudinal direction of a optical waveguide 2.

In the semiconductor laser 1 having the saturable absorption regions 3, the threshold value of the laser is high due to a loss by a saturable absorption. When light is applied to the saturable absorption regions to make them transparent, the threshold value of the laser is lowered. When a current value is supplied to the laser that is between a threshold current when the saturable absorption causes the loss and a threshold current when the saturable absorption regions are made to be transparent, the laser does not oscillate when the saturable absorption causes the loss and only a very weak light is outputted from the end face of the laser.

However, when light is allowed to be incident upon the saturable absorption regions 3 from an external part so that all the saturable absorption regions on the optical waveguide are made to be transparent, the oscillation of the laser is generated. Then, even when the light is not allowed to be incident upon the saturable absorption regions afterward, the saturable absorption regions are kept transparent due to the increase of a photon density caused by the oscillation of the laser, and the oscillation of the laser is likewise maintained.

In Fig. 1, the saturable absorption regions 3 are provided at four positions. The laser does not oscillate unless the saturable absorption regions are made to be transparent substantially at the same time by optical label signals which are serial-parallel converted. However, when the light is allowed to be incident upon the saturable absorption regions at the same time, the laser oscillates. Once the laser oscillates, the oscillation of the laser is maintained even if the optical label signals are not inputted to the saturable absorption regions afterward, the oscillation of the laser is maintained. That is, once all the saturable absorption regions are made to be transparent by the optical label signals, the laser oscillates and this state is maintained. In such away, AND of the input light can be outputted by the light.

Then, when the oscillation of the laser is generated once, the oscillation of the laser is kept. However, when the current of the laser is cut, the laser can be returned to an initial state.

When a power level is obtained that is insufficient for the optical label signals to make the saturable absorption regions transparent, an electric current may be supplied to each of the saturable absorption regions so that the electric current assists the saturable absorption region to become transparent.

The number of the saturable absorption regions is not especially limited. However, since the size of the saturable absorption regions influences the bit lengths of the optical label signal to which the saturable absorption region can respond, the size of saturable absorption region needs to be such that the saturable absorption regions adequately respond to the bit lengths of the suitable optical label signal.

FIG. 2 shows another embodiment. The same elements as those shown in FIG. 1 are designated by the same reference numerals. In FIG. 2, reference numeral 5 designates second optical waveguides provided in a direction perpendicular to the optical waveguide 2 and respectively connected to the saturable absorption regions 3. As shown in FIG. 2, the optical waveguide designated by a is connected to the saturable absorption region designated by a′. The optical waveguides designated by b, c and d are connected to the saturable absorption regions designated by b′, c′ and d′ respectively.

In such a structure, when light is introduced from the optical waveguides shown by a to d, optical label signals can be efficiently guided to the saturable absorption regions.

In the above elements, lights are inputted and then lights are outputted. However, when the outputs of the light is received by PDs and amplified by AMPs like the related example, an optical AND circuit having an electric output can be obtained.

It is most simple in manufacturing to provide a laser having such saturable absorption regions by using a Fabry-Perot type. When the output light needs to have monochromaticity, the laser may be formed in a DFB (Distributed Feed-Back) type or a DBR (Distributed Bragg Reflector) type.

Further, saturable absorption region to which the optical label signal is not connected is constantly made to be transparent by an electric current so that the operation of the region can be invalidated.

The above description merely shows specific and preferable embodiments for the purpose of explaining and exemplifying the present invention.

Accordingly, the present invention is not limited to the above-described embodiments and may include more changes and modifications within a range without departing from the essence thereof.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An optical AND element comprising:
a semiconductor laser having a plurality of saturable absorption regions on a first optical waveguide, electrodes of the saturable absorption regions being separated from each other; and
a light inputting section for inputting light into the respective saturable absorption regions.

2. The optical AND element according to claim 1, further comprising:
a current supplying section that independently supplies an electric current to the respective saturable absorption regions.

3. The optical AND element according to claim 1, wherein the light is inputted into the respective saturable absorption regions by directly connecting an optical fiber to the optical AND element.

4. The optical AND element according to claim 2, wherein the light is inputted into the respective saturable absorption regions by directly connecting an optical fiber to the optical AND element.

5. The optical AND element according to claim 1, wherein the light is inputted into the respective saturable absorption regions through the first optical waveguide.

6. The optical AND element according to claim 2, wherein the light is inputted into the respective saturable absorption regions through the first optical waveguide.

7. The optical AND element according to claim 1, further comprising:
a plurality of second optical waveguides which is connected to the saturable absorption regions respectively, and arranged in a direction perpendicular to the first optical waveguide.
